(19) United States
(12) Patent Application Publication
(10) Pub. No.: US 2025/0264343 A1
(43) Pub. Date: Aug. 21, 2025

(54) SENSOR FOR MEASURING DISTANCE OR POSITION

(71) Applicant: MICRO-EPSILON-MESSTECHNIK GMBH & CO. K.G., Ortenburg (DE)

(72) Inventors: Julian Kasberger, Ortenburg (DE); Norbert Reindl, Ortenburg (DE); Thomas Wisspeintner, Ortenburg (DE); Günter Schallmoser, Ortenburg (DE)

(21) Appl. No.: 19/116,311

(22) PCT Filed: Oct. 25, 2023
(86) PCT No.: PCT/DE2023/200217

§ 371 Date: Mar. 27, 2025

(30) Foreign Application Priority Data
Oct. 25, 2022 (DE) 10 2022 211 288.1

(51) Int. Cl. G01D 5/24

(52) U.S. Cl. CPC G01D 5/24

(57) ABSTRACT

The aim of the invention is to provide a reliable measuring behaviour in a wide variety of environmental conditions using structurally simple means. This is achieved in that a sensor (1) for measuring a distance or a position, in particular a sensor (1) which operates in a capacitive or inductive manner or on the basis of an eddy current, comprising a support (3) and comprising a sensor element (2) which is arranged on the support (3) or is integrated in the support (3), is configured and developed such that the support (3) has a hydrocarbon-ceramic laminate, is designed on the basis of a hydrocarbon-ceramic laminate or consists of a hydrocarbon-ceramic laminate.

### CROSS REFERENCE TO RELATED APPLICATIONS

This application is a National Stage Application, filed under 35 U.S.C. § 371, of International Application No. PCT/DE2023/200217, filed Oct. 25, 2023, which international application claims priority to and the benefit of German Application No. 10 2022 211 288.1, filed Oct. 25, 2022; the contents of both of which as are hereby incorporated by reference in their entireties.

### BACKGROUND

### Technical Field

The invention relates to a sensor for measurement of distance or position, in particular a capacitive or inductive or eddy-current effect sensor, having a carrier and a sensor element disposed on the carrier or integrated into the carrier.

### Description of Related Art

In the field of capacitive sensors, for example, sensor elements have long been designed in the form of sensor surfaces on carriers in the form of printed circuit boards. These carriers and printed circuit boards typically consist of a composite material composed of a matrix of synthetic resin and a reinforcement. Particularly favorable printed circuit boards (FR2) consist of the material combination of phenolic resin-paper, the most common type for printed circuit boards (FR4) made of epoxy resin and glass fiber weave. The advantage of this insulator material is that it brings sensors onto the market much more cheaply and quickly than sensors made from metal and insulation/encapsulation layers or sensors based on sintered ceramic carriers.

If printed circuit boards are used as carriers or substrate material for capacitive sensors, it is extremely important that, even in the case of varying temperature, the measurement area of the sensor (usually consisting of copper—supported by the carrier material) behaves/expands very substantially constantly or at least in a very substantially calculable and foreseeable manner, since the size of the measurement area is crucial for a capacitive measurement of distance. Inexpensive, flexibly configurable capacitive sensor surfaces are often used in industrial environments where temperatures of well over 100° C. in some cases exist in plants, depending on the application.

In the case of inductive sensors or those based on the eddy-current effect too, it is extremely important that, even in the case of varying temperature, the geometry of the sensor coil (usually consisting of copper windings-supported by the carrier material) behaves/expands very substantially constantly or at least in a very substantially calculable and foreseeable manner, since the geometry of the coil is crucial for an inductive/eddy-current measurement of distance.

Because of the layer structure of printed circuit boards, they have anisotropy in the coefficient of thermal expansion Tk. This is generally much lower in the two directions in the plane (x or y direction) than in the direction perpendicular to the plane (z direction). In the case of FR4, the coefficient of thermal expansion, for example in the plane, is about 12 to 14 ppm/° C., but perpendicular to that about 70 ppm/° C. Typically, depending on the manufacturer and depending on other additives, FR4 has a glass transition temperature Tg of 115° C. to 140° C. At this temperature, the mechanical and electrical characteristics of the insulation layer are subject to enormous change, and the coefficient of thermal expansion Tk of the printed circuit board perpendicular to the plane (i.e. in measurement direction) sometimes “jumps” from a typical 70 ppm/C to about 300 ppm/° C. Increasingly poorer measurement quality is accompanied here by the risk that the printed circuit board vias will be subject to enormous forces and break off, resulting in a sensor defect.

The recommended maximum operating temperature of these FR4-based printed circuit boards is inadequate for many applications, since the latter is stated by most printed circuit board manufacturers to be about 25° C. below the glass transition temperature Tg. Most FR4 printed circuit boards have a Tg of 135° C., and specialty FR5 printed circuit boards a Tg of 150° C. (high-Tg printed circuit boards), but this does not permit sustained working at temperatures of 150° C. In addition, conventional FR4 printed circuit board sensors, because there is too great a difference in coefficients of expansion of the individual components (printed circuit board-based measuring element—already made of at least 2 different main materials: copper and carrier material; if necessary glued into a sensor housing-typically made of stainless steel), often show unpredictable behavior in distance measurement in the event of temperature increases. This is due to deflection of the capacitive sensor (printed circuit board) caused by mechanical stress as a result of different expansion of the individual components in the plane perpendicular to the measurement direction. In the case of sensors that operate on the basis of coils (inductive or eddy-current sensors), the geometry of the coil can change (e.g. change in diameter), which can lead to a change in inductance and hence distortion of the measured value.

As an alternative to printed circuit boards made from FR materials, ceramic carriers are used in applications with elevated temperature requirements. These may be single-layer ceramic substrates that are provided with conductor tracks in thick-film printing technology in what is called hybrid methodology. Another option is multilayer ceramic substrates consisting of what is called a green foil, which are likewise printed and assembled in a sintering process to form a rigid printed circuit board. Depending on the temperature range, they are referred to as LTCC (low-temperature cofired ceramics) or HTCC (high-temperature cofired ceramics). However, a common factor in all these ceramic technologies is that the resulting printed circuit board constitutes a rigid, very brittle substrate that withstands mechanical stresses only to a low degree, if at all. Because of the different manufacturing steps (printing, sintering, singularizing by laser or waterjet cutting, etc.), production is likewise very complex and costly, and therefore these methodologies are only used in the case of high temperature demands.

### BRIEF SUMMARY

It is an ever-present task in the field of such sensors to be able to develop a variably configurable sensor or an element of a sensor which is designable and also manufacturable in a short period of time and which delivers very substantially constant measurement characteristics with maximum independence from the environment, in view of the sometimes high demands that arise from the measurement environment—mainly in the industrial sector.

It is therefore an object of the present invention to specify a sensor of the type specified at the outset that enables reliable measurement characteristics under a wide variety of different environmental conditions with simple construction means.

The above object is achieved in accordance with the invention by a sensor having the features of the broadest claim herein. Accordingly, the sensor has been designed and developed in that the carrier comprises a hydrocarbon-ceramic laminate, is based on a hydrocarbon-ceramic laminate or consists of a hydrocarbon-ceramic laminate.

It has first been recognized within the scope of the invention that the carrier material customarily used in the known sensor leads to restriction of the use of the known sensor under a wide variety of different environmental conditions. It has then further been recognized within the scope of the invention that the above object is achieved in a surprisingly simple manner by use specifically of a hydrocarbon-ceramic laminate in the region of the carrier. More particularly, the carrier comprises a hydrocarbon-ceramic laminate, the carrier is based on a hydrocarbon-ceramic laminate, or the carrier consists of a hydrocarbon-ceramic laminate. Different inventive configurations are implementable here, in which the carrier in one variant consists entirely of a hydrocarbon-ceramic laminate for example. A carrier based on a hydrocarbon-ceramic laminate or based on hydrocarbon-ceramic laminates can offer a virtually direct replacement for conventional carriers in flexibly configurable, inexpensive capacitive or inductive/eddy-current sensors, especially in the field of capacitive or inductive/eddy-current sensors with printed circuit board carriers. Hydrocarbon-ceramic laminates are composite materials which may have a matrix of hydrocarbon resin and a reinforcement of glass fiber weave, where the hydrocarbon resin may have been filled with mineral fillers (in powder form). These are generally ceramic fillers, but other mineral fillers are also conceivable, for example quartzes. By means of a high degree of filling, particularly favorable properties similar to the ceramic materials described at the outset are achieved. Hydrocarbon-ceramic laminates therefore exhibit very constant mechanical and electrical characteristics even under significantly fluctuating ambient conditions, for example at up to about 280° C. For instance, the coefficient of thermal expansion is very homogeneous and has zero or only very low anisotropy. Furthermore, the coefficient of thermal expansion is in the range of 10 to 12 ppm/° C., which is close to the Tk of copper.

Consequently, the sensor of the invention provides a sensor that enables reliable measurement characteristics under a wide variety of different environmental conditions with simple construction means.

With regard to particularly simple and reliable construction, the carrier may be designed as a printed circuit board or include a printed circuit board. The use of printed circuit boards as carrier has been proven in practice and enables flexible and inexpensive production of a sensor.

With regard to particularly reliable and simple manufacture of the sensor, the sensor element may take the form of a sensor element introduced into the carrier or applied to or etched into the carrier or introduced into or applied to or etched into a metal layer on the carrier, or of a sensor surface introduced into the carrier or applied to or etched into the carrier or introduced into or applied to or etched into a metal layer on the carrier. If a sensor element has one or more coils, these may be introduced or applied or etched in the form of conductor tracks or coils.

In capacitive sensors, the sensor element may consist of two-dimensional electrodes that form the measuring electrode, a guard electrode and, if necessary, a ground area. For inductive or eddy-current sensors, the sensor element may consist of one or more coils that form inductances.

The sensor element may be structured by suitable methods in a conductive layer on or in the carrier and hence the desired surface or coil can be elaborated. Methods here may include (selective) etching or laser ablation of copper surfaces, or the applying of metal surfaces or conductors by coating (sputtering, thick-film, thin-film) or photolithography methods. Also conceivable is a combination of several processes, for example by reworking a coil or surface that has been produced by coating by laser processing. Metal surfaces or conductor tracks are typically made from copper in printed circuit board technology. But other metals are also suitable, especially for coating processes. This allows flexible configuration of the size of the sensor element in accordance with the respective application.

In a specific design, the sensor may have a layer structure of the hydrocarbon-ceramic laminate and at least one surface of copper or metal and/or at least one copper conductor track or metal conductor track. In a more specific manner, the surface and/or the copper conductor track or metal conductor track may be applied to or incorporated into the hydrocarbon-ceramic laminate. With such a layer structure, there is a wide variety of different configuration options, and so reliable adaptation of the sensor configuration to a particular application is possible.

For reliable and simple implementation of a capacitive sensor, the at least one surface of copper or metal may very specifically form an electrode surface or sensor surface for a capacitive measurement.

For reliable and simple implementation of an inductive or eddy-current effect sensor, the at least one coil made of copper or metal may very specifically form an inductance for an inductive or eddy-current effect measurement.

As required, the sensor may be disposed in a housing, have a housing or be coupled to a housing. In this regard too, the configuration can be flexibly adapted to the respective application requirements of the sensor, and a particularly protected configuration and hence particularly reliable measurement characteristics can be assured by an implementation with a housing.

In a specific embodiment, the housing may be made of metal. Because of the stability of metal, it is possible to assure a particularly high level of protection for a sensor element disposed in the housing. Alternatively or additionally thereto, the housing may have at least one assembly passage and/or at least one assembly element. Such an assembly passage and/or assembly element can achieve secure positioning of the sensor by means of the housing at a site of use. Secure positioning enables reliable measurements with the sensor.

In a manner which is also particularly simple and reliable in construction terms, the sensor or a terminal area of the sensor may have been overmolded or have an injection-molded envelope. Such an overmolding or injection-molded envelope may replace a housing and/or be made in a reliable manner using plastic.

With regard to particularly reliable actuation and/or transmission of measurement data to evaluation electronics, the sensor element may be contacted with evaluation electronics via a coaxial or triaxial cable. A particularly high shielding effect can be achieved by means of a triaxial cable.

With regard to a particularly simple implementation, for example of a gap sensor, the carrier may have at least two sensor elements that measure in different directions. These two directions may point in opposite directions, making gap widths particularly easy to measure.

In one working example, the sensor or the carrier, with regard to a particularly stable configuration of the sensor and hence with regard to particularly reliable measuring characteristics, may have several plies of a hydrocarbon-ceramic laminate.

Moreover, with regard to a particularly stable configuration of the sensor, one or more plies of a glass fiber weave may be embedded into the hydrocarbon-ceramic laminate. Each ply of a hydrocarbon-ceramic laminate may be assigned to one or more plies of a glass fiber weave. In specific terms, several plies of a glass fiber weave may be embedded or disposed in one ply of a hydrocarbon-ceramic laminate.

In one working example, the hydrocarbon-ceramic laminate may include at least one filler, preferably a ceramic powder, further preferably with a high degree of filling. This can likewise achieve a particularly stable sensor construction.

With regard to a particularly high shielding effect and hence reliable measurement, the sensor element may have a guard electrode in one ply of the hydrocarbon-ceramic laminate, and the sensor or the carrier may have an additional guard electrode in a further ply of the hydrocarbon-ceramic laminate. This enables implementation of particularly effective shielding, effectively in two stages.

With one working example of the sensor of the invention, it is possible to implement a capacitive sensor or an inductive sensor or one that operates by the eddy-current effect for the measurement of distance and/or position with a sensor element which has been integrated into a flat substrate serving as carrier or applied to such a flat substrate, where the substrate consists of hydrocarbon-ceramic laminates or may include hydrocarbon-ceramic laminates.

### BRIEF DESCRIPTION OF THE FIGURES

There are various options for configuration and development of the teaching of the present invention in an advantageous manner. In this regard, reference is made firstly to the subsidiary claims and secondly to the elucidation of preferred working examples of the sensor of the invention that follows. In association with the elucidation of the preferred working examples with reference to the drawing, generally preferred embodiments and developments of the teaching are also elucidated. The figures show:

FIG. 1 a side view, in partial cross section, of a first working example of the sensor of the invention,

FIG. 2 a side view, in partial cross section, and a top view of a second working example of the sensor of the invention,

FIG. 3 a side view, in partial cross section, and a top view of a third working example of the sensor of the invention,

FIG. 4 a perspective view of the third working example of the sensor of the invention from FIG. 3,

FIG. 5 a side view, in partial cross section, a further side view, in partial cross section, and a top view of a fourth working example of the sensor of the invention,

FIG. 6 a side view, in partial cross section, and a top view, of a fifth working example of the sensor of the invention,

FIG. 7 a perspective view of a sixth working example of the sensor of the invention,

FIG. 8 a section view of a hydrocarbon-ceramic laminate and

FIG. 9 a section view of a sensor of the invention with a single-ply or multi-ply construction.

In the working examples of the inventive sensor 1 that have been described hereinafter, the same reference numerals denote the same components.

### DETAILED DESCRIPTION OF VARIOUS EMBODIMENTS

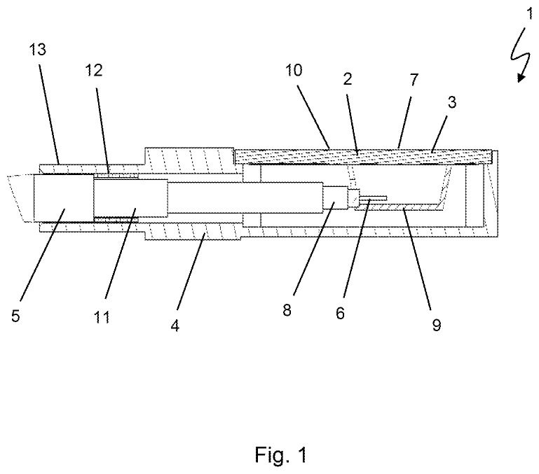

FIG. 1 shows a first working example of the inventive sensor 1, which has a specific capacitive measuring element/sensor element 2 that forms a material composite with a printed circuit board 3 serving as a carrier 3, which includes a hydrocarbon-ceramic laminate and copper surfaces and/or wires. This composite material has excellent thermal stability over a complete temperature range for use. The sensor element 2 is located in a metal housing 4. Contacts are connected via a coaxial or triaxial cable 5.

There follows a description of the design with a triaxial cable 5. This has the advantage that an improved shielding effect is achieved compared to a coaxial connection of the sensor 1. A center conductor 6 of the cable 5 makes contact with a measuring electrode 7 on the sensor element 2. An inner shielding cable 8 is electrically connected to a metallic shield cap 9, disposed on the reverse side of the sensor element 2. The shield cap 9 is conductively connected to a guard electrode 10 on the front/measuring side of the sensor element 2. With this arrangement, it is possible to achieve active shielding—also called guard technology—of the measuring electrode 7. An outer shield 11 of the cable 5 is conductively connected to the housing 4. For this purpose, a metal support sleeve 12 has been pushed onto the cable 5. The support sleeve 12 has two functions: firstly, it serves to make electrical contact between the outer shield 11 and the housing 4, and secondly it braces the cable 5 against a crimp 13 by which the cable 5 is mechanically connected to the housing 4.

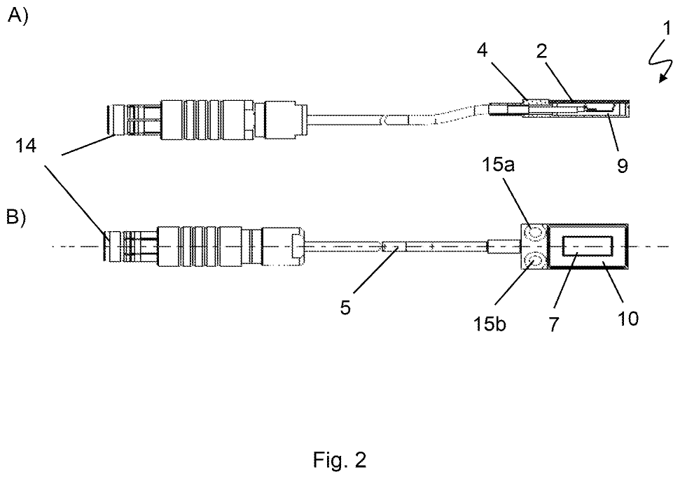

FIG. 2 shows a second working example of the inventive sensor 1 in a lateral diagram A and in top view B. The sensor 1 has a triaxial plug 14 for connection to the evaluation electronics (not shown here). The housing 4 has two assembly holes 15a, 15b for mounting or positioning the sensor 1 at a suitable site. For example, the housing 4 can be secured to a suitable component and/or positioned by means of screws (not shown here) guided through the mounting holes 15a, 15b.

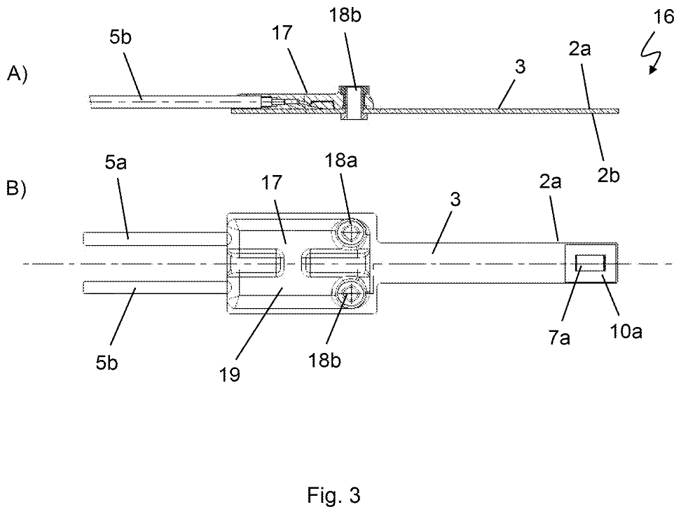

FIG. 3 shows a third working example of a sensor of the invention in the form of a capacitive gap sensor 16 in lateral view A and top view B. As in the first working example shown in FIG. 1, in this gap sensor 16 too, a material composite composed of capacitive measuring element/sensor element 2 and a printed circuit board 3 serving as a carrier 3 is formed, where the material composite comprises a hydrocarbon-ceramic laminate and copper surfaces and/or wires.

The gap sensor 16 specifically has two sensor elements 2a, 2b, formed in the printed circuit board 3. One sensor element 2a measures in one direction (upward in the figure), the other sensor element 2b in the opposite direction (downward in the figure). This allows the width of gaps to be measured by measuring the distance to one side of the gap and, at the same time, the distance to the second side of the gap, and determining the width or breadth of the gap therefrom.

The sensor 16 does not have a housing, but consists solely of the above-described material composite composed of sensor elements 2a, 2b and printed circuit board 3 in the measurement area. This is possible owing to the good and stable mechanical properties of the hydrocarbon-ceramic laminate. In the terminal region 17, the two sensor elements 2a, 2b are each contacted with a triaxial cable 5a, 5b in the manner already known from FIG. 1. In addition, for mechanical securing or positioning of the sensor 16, two screw eyelets 18a, 18b or passages are provided in the printed circuit board 3 or formed in the printed circuit board 3. The entire connection area 17 including the screw eyelets 18a, 18b has been overmolded with hotmelt—fusible plastic—19. This serves firstly for mechanical fixing, and secondly for sealing against dusts and liquids, and serves as a replacement for the housing. However, other injection molding methods can also be used rather than hotmelt.

The sensor 16 is an example of how flexibly configurable such sensors 16 are. Together with the terminal region 17 and cables 5a, 5b, this printed circuit board 3 forms a complete, very thin capacitive sensor 16 with extremely good performance compared to comparable sensors for monitoring a gap between two conductive objects. The thickness of such a sensor may, for example, be in the range from 0.5 mm to 1.0 mm in the case of a single-layer structure of the hydrocarbon-ceramic laminate, preferably 0.8 mm.

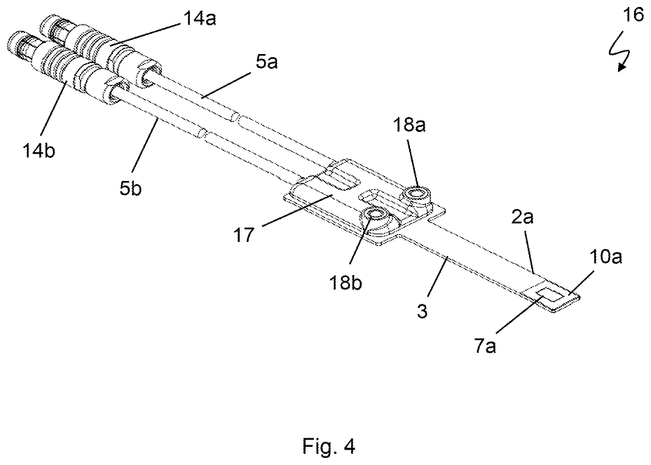

FIG. 4 shows the gap sensor 16 in a perspective overall view with triaxial plugs 14a, 14b.

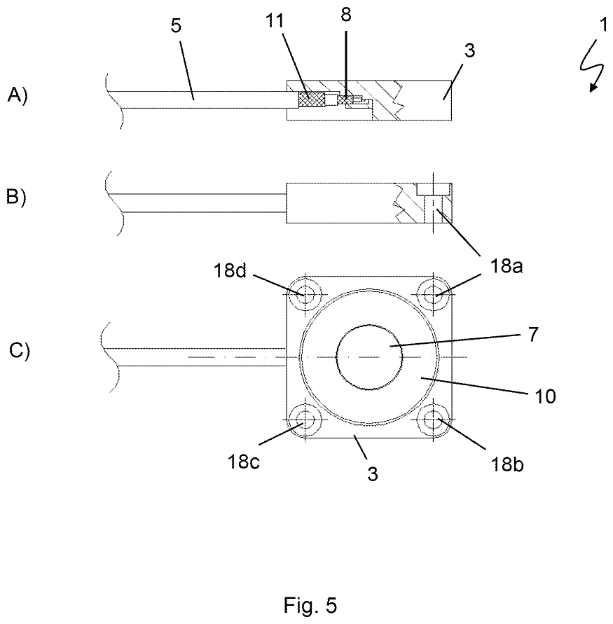

FIG. 5 shows a fourth working example of an inventive sensor 1—A: section through a center axis, B: section with a lateral view of an assembly hole, C: top view—, designed solely by means of a printed circuit board 3 with sensor element and with already integrated assembly holes 18a, 18b, 18c, 18d and a wire 5 without an additional housing. The sensor 1 has several plies of a hydrocarbon-ceramic laminate. The middle (core) layer has a thickness of about 1.5 mm. Three plies each, having a thickness of about 0.5 mm, are laminated on the bottom side and on the top side, so as to achieve a total thickness of the sensor of about 5 mm. The assembly holes 18a, 18b, 18c, 18d can be produced by drilling, machining or other methods suitable for printed circuit boards 3.

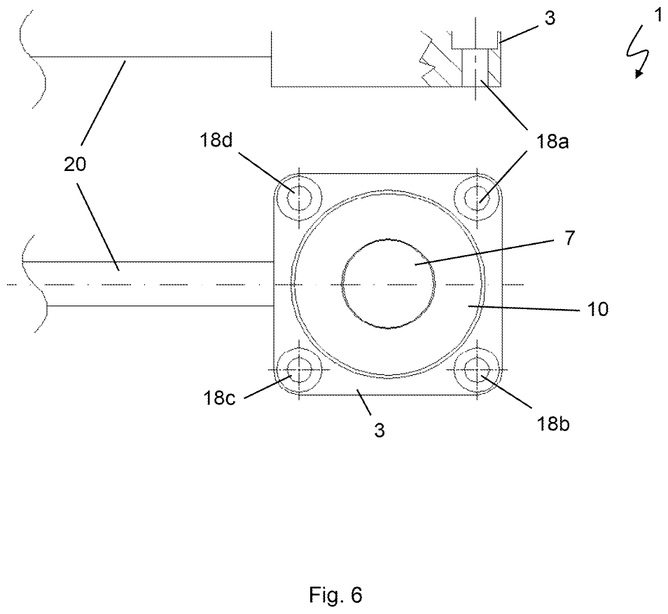

With this option of three-dimensional machining and processing as well on printed circuit boards 3, it is also possible here to configure capacitive distance sensors in a flat design, for example, which offer an assembly option even without additional parts. A particularly flat design can be achieved when a flat cable 20 is used rather than a cable 5 of round cross section, as shown in FIG. 6.

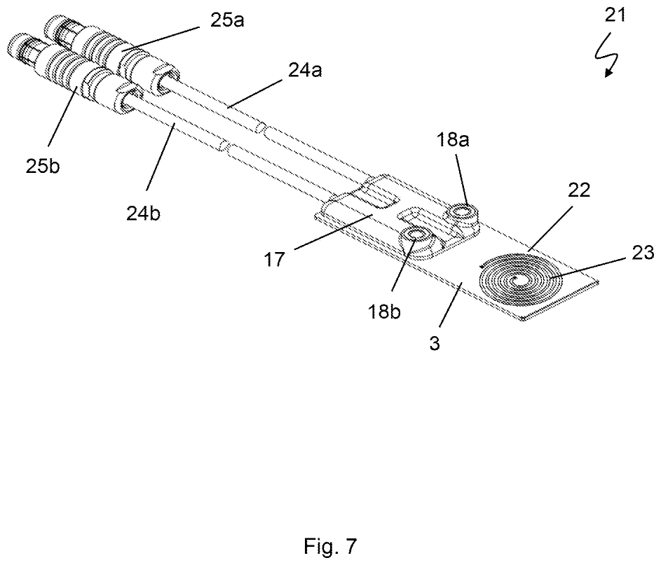

FIG. 7 shows a sixth working example of a sensor of the invention in the form of an eddy-current sensor 21 as a flat sensor in a perspective overall view. The sensor element 22 consists of a coil 23 disposed on the carrier 3. Coaxial cables 24a, 24b are used here with coaxial plugs 25a, 25b. As in the first working example shown in FIG. 1, in this area sensor 21 too, a material composite composed of a sensor element 22 in the form of a coil 23 and a printed circuit board 3 serving as a carrier 3 is formed, where the material composite comprises a hydrocarbon-ceramic laminate and copper windings and/or wires.

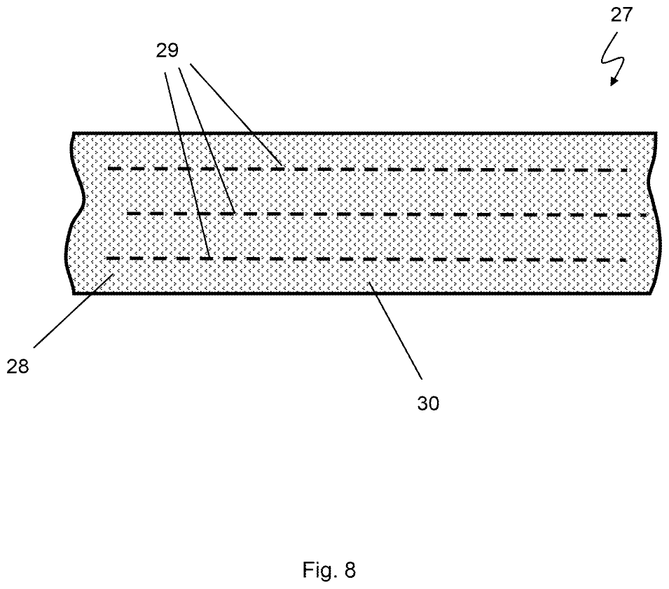

FIG. 8 shows the construction of a hydrocarbon-ceramic laminate 27 in section view. Several plies of a glass fiber weave 29 have been embedded (laminated) into a matrix 28. The matrix 28 contains fillers 30 composed of ceramic powder with a high filling level.

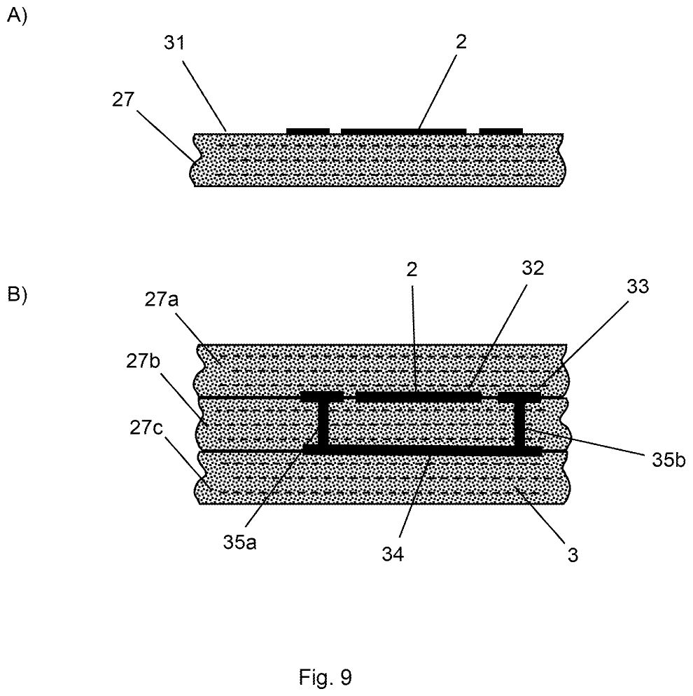

FIG. 9 shows a partly cross-sectional diagram of a capacitive sensor element 2-A: on the surface 31 of a single-ply hydrocarbon-ceramic laminate 27 and B: embedded into a multi-ply printed circuit board 3 composed of hydrocarbon-ceramic laminates 27a, 27b, 27c. The sensor element 2 has a measuring electrode 32 and a guard electrode 33, in a circular arrangement. In order to achieve an improved shielding effect, an additional guard electrode 34 is disposed in a further position on the printed circuit board and is electrically connected to the guard electrode 33 through vias 35.

Advantages and important aspects of working examples of the sensor of the invention are elucidated hereinafter:

A virtually direct replacement for conventional FR4 printed circuit boards—for flexibly configurable, inexpensive capacitive or inductive or eddy current effect sensors based on printed circuit board technology—is offered by printed circuit boards based on hydrocarbon-ceramic laminates.

With coefficients of thermal expansion that are very well adapted to the copper conductor material, and hence also to stainless steel for any sensor housing needed, these carrier materials or printed circuit board materials, which are now offered almost with almost 1:1 equivalence to FR4 by many printed circuit board manufacturers, are of very good suitability for use in carriers or printed circuit boards of sensors of the invention in fluctuating ambient conditions. The good processibility of the materials, which encompasses virtually all processing methods used in printed circuit board manufacture, makes this material even more attractive for the inventive configurations and applications.

The glass transition temperature, which is otherwise critical in the case of FR4, is above 280° C. here. Up to this temperature, the hydrocarbon-ceramic laminates (HCL) described exhibit extremely constant electrical and mechanical characteristics, which is ideal for developing a capacitive sensor inexpensively and in the shortest possible time, and with very predictable behavior in the event of elevated temperature fluctuations.

| Overview of | | | |
|---|---|---|---|
| values: | HCL | FR4 | FR5 (HTg) |
| Tg | 280° C. | 120 to 150° C. | to 170° C. |
| (glass transition temperature) | | | |
| Td | 390° C. | about 300° C. | about 350° C. |
| (breakdown temperature) | | | |
| Tk (x/y) in ppm/° C. | 10/12 | about 20 | about 20 |
| Tk (z) in ppm/° C. | 32 | 45 to 70 | 45 to 70 |
| Dielectric constant | 3.5 | about 4.6 | about 4.8 |
| Thermal dielectric | 50 | — | — |
| coefficient in ppm/° C. | | | |

With such hydrocarbon-ceramic laminates, it is very easy and inexpensive to produce capacitive or inductive or eddy-current effect sensors that cover a considerably larger temperature range than sensors with conventional FR4 printed circuit boards: In a layer structure, it is possible for this purpose to apply or introduce copper surfaces or copper conductor tracks on or within the laminate by known printed circuit board technology. The copper surfaces here form the electrode surfaces required for capacitive measurement (measuring electrode, guard electrode and ground area) or coils (if necessary primary and secondary coils), which are contacted with the copper wires, if necessary through electrical vias. Because of the very similar coefficients of expansion Tk of the hydrocarbon-ceramic laminate and the copper surfaces or the metal housing, only very small mechanical stresses, if any, that could impair a measurement or even destroy the sensor occur even at higher temperatures.

It is particularly advantageous that the manufacturing steps customary in FR4 technology can be used almost unchanged. For example, it is also possible to laminate flexible printed circuit boards for the connection of a sensor of the invention to or between the plies of hydrocarbon-ceramic laminates. This means that flat cables for contacting the sensor elements can be implemented in a very simple and inexpensive way.

With regard to further advantageous embodiments of the sensor of the invention, for avoidance of repetition, reference is made to the brief summary section of the description and to the appended claims.

Finally, it should be pointed out explicitly that the working examples described above serve merely for discussion of the teaching claimed, but do not limit it to the working examples.

1-15. (canceled)

16. A sensor (1) for measurement of distance or position, in particular a capacitive or inductive or eddy-current effect sensor (1), having a carrier (3) and a sensor element (2) disposed on the carrier (3) or integrated into the carrier (3), wherein the carrier (3) comprises a hydrocarbon-ceramic laminate (27), is based on a hydrocarbon-ceramic laminate (27) or consists of a hydrocarbon-ceramic laminate (27).

17. The sensor as claimed in claim 16, wherein the carrier (3) is designed as a printed circuit board (3) or includes a printed circuit board (3).

18. The sensor as claimed in claim 16, wherein the sensor element (2) takes the form of a sensor element (2) introduced into the carrier (3) or applied to or etched into the carrier (3) or introduced into or applied to or etched into a metal layer on the carrier, or of a sensor surface introduced into the carrier (3) or applied to or etched into the carrier (3) or introduced into or applied to or etched into a metal layer on the carrier.

19. The sensor as claimed in claim 16, wherein the sensor (1) has a layer structure composed of the hydrocarbon-ceramic laminate (27) and at least one surface of copper or metal and/or at least one copper conductor track or metal conductor track which may be applied to or introduced into the hydrocarbon-ceramic laminate (27).

20. The sensor as claimed in claim 19, wherein the at least one surface of copper or metal forms an electrode surface or sensor surface for a capacitive measurement.

21. The sensor as claimed in claim 16, wherein the sensor (1) is disposed within a housing (4), has a housing (4) or is coupled to a housing (4).

22. The sensor as claimed in claim 21, wherein the housing (4) is made of metal and/or has at least one assembly passage (15, 18) and/or at least one assembly element.

23. The sensor as claimed in claim 16, wherein the sensor (1) or a terminal region (17) of the sensor (1) has been overmolded or has an injection-molded envelope.

24. The sensor as claimed in claim 16, wherein the sensor element (2) is contacted with evaluation electronics via a coaxial or triaxial cable (5).

25. The sensor as claimed in claim 16, wherein the carrier (3) has at least two sensor elements (2a, 2b) that measure in different directions.

26. The sensor as claimed in claim 25, wherein the sensor is a gap sensor with sensor elements (2a, 2b) that measure in opposite directions.

27. The sensor as claimed in claim 16, wherein the sensor (1) or the carrier (3) has several layers of a hydrocarbon-ceramic laminate (27).

28. The sensor as claimed in claim 16, wherein one or more layers of a glass fiber weave (29) is/are embedded in the hydrocarbon-ceramic laminate (27).

29. The sensor as claimed in claim 16, wherein the hydrocarbon-ceramic laminate (27) includes at least one filler (30).

30. The sensor as claimed in claim 29, wherein the at least one filler (30) is a ceramic powder.

31. The sensor as claimed in claim 16, wherein the hydrocarbon-ceramic laminate (27) includes at least one filler (30) with a high degree of filling.

32. The sensor as claimed in claim 16, wherein the sensor element (2) has a guard electrode (33) in one ply of the hydrocarbon-ceramic laminate (27) and the sensor (1) or the carrier (3) has an additional guard electrode (34) in a further ply of the hydrocarbon-ceramic laminate (27).
